(19) United States
(12) Patent Application Publication
(10) Pub. No.: US 2017/0271408 A1
(43) Pub. Date: Sep. 21, 2017

(54) MEMORY CELL WITH A MULTI-LAYERED SELECTOR

(71) Applicant: Hewlett Packard Enterprise Development LP, Houston, TX (US)

(72) Inventors: Jianhua Yang, Palo Alto, CA (US); Ning Ge, Palo Alto, CA (US); Zhiyong Li, Foster City, CA (US); Richard H. Henze, San Carlos, CA (US)

(21) Appl. No.: 15/329,896

(22) PCT Filed: Jan. 28, 2015
(86) PCT No.: PCT/US2015/013327

§ 371 Date: Jan. 27, 2017

(51) Int. Cl. H01L 27/24; H01L 45/00

(52) U.S. Cl. CPC H01L 27/2418; H01L 45/1608; H01L 45/146

(57) ABSTRACT

A method of forming a multi-layered selector of a memory cell is described. In the method, a memory element of the memory cell is formed. The memory element stores information. A multi-layered selector of the memory cell is formed by alternating deposition of at least a dielectric layer and a first diffusion layer. The first diffusion layer includes fast diffusive ions. The multi-layered selector is coupled to the memory element in a memory cell.

### BACKGROUND

Crossbar memory arrays are used to store data. A crossbar memory array may be made up of a number of memory elements. Data may be stored to memory elements by assigning logic values to the memory elements within the memory arrays. For example, the memory elements may be set to 0, 1, or other values to store data in a memory element of a memory array. Much time and effort has been expended in designing and implementing nanoscale memory arrays.

Resistive memory elements referred to as memristors are devices that may be programmed to different resistance states by applying electrical voltage or currents to the memristors. After programming, the resistance state of the memristors may be read by applying an electrical bias without disturbing the resistance states when a lower electrical bias is applied. The state of the memristors remains stable over a specified time period long enough to regard the device as non-volatile.

### BRIEF DESCRIPTION OF THE DRAWINGS

The accompanying drawings illustrate various examples of the principles described herein and are a part of the specification. The illustrated examples are given merely for illustration, and do not limit the scope of the claims.

FIG. 1 is a diagram of a multi-layered selector in a crossbar array according to one example of the principles described herein.

FIG. 2 is a cross-sectional diagram of a multi-layered selector according to one example of the principles described herein.

FIG. 3 is a flow diagram of a method for forming a multi-layered selector of a memory cell, according to one example of the principles described herein.

FIG. 4 is a flow diagram of a method for forming a multi-layered selector of a memory cell, according to another example of the principles described herein.

FIGS. 5A-5C are cross-sectional diagrams of a multi-layered selector, according to examples of the principles described herein.

Throughout the drawings, identical reference numbers designate similar, but not necessarily identical, elements.

### DETAILED DESCRIPTION

Increasingly smaller computing devices have ed to an increased focus on developing smaller components, such as memory arrays. Memristor arrays made up of resistive memory elements called memristors are one example of reduced-size memory arrays. Memory arrays of memory elements such as memristors may be used in a variety of applications, including random access memory, non-volatile solid state memory, programmable logic, signal processing, control systems, pattern recognition, and other applications,

Each memory element in an array can represent at least two logic values, for example a 1 and a 0. Memory elements such as memristors may use resistance levels to indicate a particular logic value. In using a memristor as an element in a memory array, a digital operation is emulated by applying programming energy such as voltage pulses of different values, polarities, or duration to place the memristor in a “low resistance state” which resistance state is associated with a logical value, such as “1.” Similarly, a voltage pulse of a different polarity, value, or duration may place the memristor in a “high resistance state,” which resistance state is associated with another logical value, such as “0.”

The ability to change a memristor resistance state is dependent on a switching voltage of the memristor. For example, each memristor has a switching voltage which refers to a voltage potential across a memristor which effectuates a change in the resistance state of the memristor. For example, a switching voltage of a memristor may be between 1-2 volts (V). In this example, a voltage potential across the memristor that is greater than the switching voltage (i.e., the 1-2 V) causes the memristor to change between resistance states. Throughout the specification reference is made to a supplied voltage or applied voltage however, in some examples, the programming energy may be supplied by a current source.

To determine what resistance state, and corresponding logic value, is indicated by a memristor, an output current may be collected and analyzed. For example, if a write voltage is applied to a target memory element, a write current passing through the target memory element may be collected. Based on the write voltage and the collected write current, a resistance level of the target memory element and corresponding written logic value may be ascertained. Similarly, if a read voltage is applied to a target memory element, a current passing through the target memory element may be collected. Based on the read voltage and the collected read current, a resistance level of the memristor and the corresponding stored logic value may be ascertained. While crossbar memory arrays may offer high density storage, certain characteristics may affect their usefulness in storing information.

For example, in a crossbar a first number of conducting lines (row lines) and a second number of conducting lines (column lines) are positioned to form a grid, with memory elements disposed at each intersection. A voltage potential is applied across a memory element by passing voltages along a row line and column line that correspond to a target memory element. In applying a portion of an access voltage to a target row line and another portion of the access voltage to a target column line, other memory elements that fall along these target lines that are not the target memory element may also see a voltage drop, albeit a voltage drop smaller than the voltage drop across the target memory element. The voltage potential across these partially-selected memory elements generates additional current paths in the crossbar array. These additional current paths are referred to as sneak currents and are undesirable as they are noise and obfuscate the intended target output current. Large sneak currents may lead to a number of issues such as saturating the current of driving transistors and increasing power consumption. Moreover, large sneak currents may introduce large amounts of noise which may lead to inaccurate or ineffective memory reading and writing operations.

Accordingly, in some examples, a selector may be coupled to a memory element. A selector is an element that is used to either allow or prevent current from flowing to a corresponding memory element. If current does not flow through the memory element, current is not collected. The selector may have a threshold voltage. An applied voltage less than the threshold voltage does not pass a large current through the corresponding memory element and a portion of a sneak current may be reduced. Thus a selector works to isolate a target memory cell and reduce overall sneak current in the crossbar array.

Selectors may be nonlinear meaning that a certain change in voltage applied across the selector may drive a disproportionate change in the current passing through the selector. In other words, a nonlinear selector may be used to isolate unselected memory elements and thereby reduce sneak current in an array such as a crossbar array. However, some highly nonlinear selectors that effectively isolate the corresponding memory element may be difficult to manufacture in a semiconductor and circuit manufacturing facility. For example, a co-sputtering process of multiple oxides may use additional, new, and costly manufacturing operations and equipment.

The devices and methods described herein may alleviate these and other complications. More specifically, the present systems and methods describe fabrication of a selector that is highly nonlinear and is simple and cost-effective to manufacture, and can be fabricated using machinery that may already be present in a manufacturing site. Forming the selector may include depositing alternating layers of material having different ion diffusion rates from those in a dielectric layer.

The present specification describes a method for forming a multi-layered selector of a memory cell. In the method, a memory element of the memory cell is formed. The memory element stores information. A multi-layered selector of the memory cell is formed by alternating deposition of at least a dielectric layer and a first diffusion layer. The first diffusion layer includes fast diffusive ions. The multi-layered selector is coupled to the memory element in a memory cell.

The present specification describes a memory cell with a multi-layered selector. The cell includes a memory element that includes a bottom electrode disposed on a substrate, a top electrode disposed above the bottom electrode, and a switching layer disposed between the top electrode and the bottom electrode. The cell also includes a multi-layered selector communicatively coupled to the memory element. The multi-layered selector includes alternating layers of at least a dielectric material and a first diffusion layer. The first diffusion layer includes at least one of silver, copper, nickel, silver oxide, copper oxide, and nickel oxide.

The present specification describes a method for forming a memory cell with a multi-layered selector. In the method, a bottom electrode of a memristive memory element is formed on a substrate, a switching layer of the memristive memory element is deposited on a top surface of the bottom electrode, and a top electrode of the memristive memory element is deposited on a top surface of the switching layer. Also in the method, a nonlinear multi-layered selector with fast diffusive conduction channels is formed by alternately depositing layers of each of a dielectric material including at least one of silicon oxide, hafnium oxide, tantalum oxide, zirconium oxide, aluminum oxide, titanium oxide, silicon nitride, and aluminum nitride; a first diffusion layer having ions with a first diffusion rate, the first diffusion layer including at least one of silver oxide, copper oxide, nickel oxide, silver, copper, and nickel; and a second diffusion layer having ions with a second diffusion rate, in which the second diffusion rate is less than the first diffusion rate and in which the second diffusion layer includes at least one of silver oxide, copper oxide, nickel oxide, silver, copper, and nickel. The nonlinear multi-layered selector is communicatively coupled to at least one of the top electrode of the memristive memory element and the bottom electrode of the memristive memory element.

The devices and methods described herein may allow for a simple manufacturing process for a highly nonlinear and high current density selector to effectively reduce the effects of sneak current in a crossbar array and to efficiently isolate unselected memory cells from selected memory cells. Moreover, by implementing a layering process in forming the multi-layered selector, greater flexibility in selector manufacturing is achieved. The layering approach also offers increased controllability to selector fabrication. Still further by layering a first diffusion layer with fast diffusive ions, localized conduction channels of the fast diffusive metal are formed in the dielectric layer.

As used in the present specification and in the appended claims, the term “memristor” may refer to a passive two-terminal circuit element that changes its electrical resistance under sufficient electrical bias.

Further, as used in the present specification and in the appended claims, the term “target” may refer to a memory element that is to be written to or read from. A target first line and a target second line may be first lines and second lines that correspond to the target memory element. A target memory element may refer to a memory element with a non-conductive selector as opposed to a conductive selector.

Still further, as used in the present specification and in the appended claims, the term “partially-selected memory element” may refer to a memory element that falls along a target first line or a target second line. The partially-selected memory elements may have a voltage drop that is less than a voltage drop of the target memory element. A partially-selected memristor may receive either the first portion of the access voltage passed through a target first line or the second portion of the access voltage passed through a target second line.

Still further, as used in the present specification and in the appended claims the term “access voltage” may refer to a voltage that is applied to a memory element. The access voltage may be a write voltage that is larger than a switching voltage of a memory element, or may be a read voltage that is less than the switching voltage of the memory element. By comparison, a non-access voltage may refer to a voltage that is not greater than either a read voltage or a write voltage. The access voltage may be greater than a threshold voltage for a selector, the threshold voltage being a voltage sufficient to activate the selector into an increased conductivity state and a non-access voltage may be less than the threshold voltage for a selector.

Still further, as used in the present specification and in the appended claims, the term “nonlinear” may refer to a property of the selector or memristor wherein a change in voltage applied across the selector or memristor results in a disproportionate change in current flowing through the selector or memristor, respectively.

Even further, as used in the present specification and in the appended claims, the term “diffusion layer” may refer to a layer of the multi-layered selector that has cations that diffuse through a diffusion region of the selector.

Even further, as used in the present specification and in the appended claims, the term “fast diffusive ions” refers to ions that diffuse faster than normal oxygen vacancies and oxygen anions in oxides at the same temperature. Examples of such fast diffusive ions include silver, copper and nickel in silver oxide, copper oxide, nickel oxide or other dielectric oxides.

Yet further, as used in the present specification and in the appended claims, the term “a number of” or similar language may include any positive number including 1 to infinity; zero not being a number, but the absence of a number.

In the following description, for purposes of explanation, numerous specific details are set forth in order to provide a thorough understanding of the present systems and methods. It will be apparent, however, to one skilled in the art that the present apparatus, systems, and methods may be practiced without these specific details. Reference in the specification to “an example” or similar language indicates that a particular feature, structure, or characteristic described is included in at least that one example, but not necessarily in other examples.

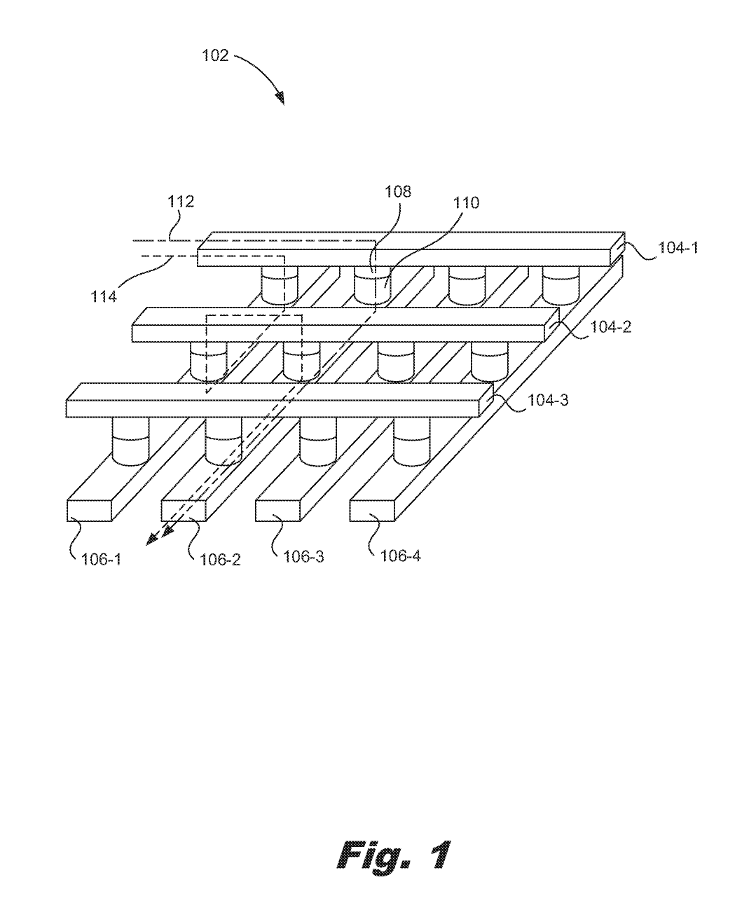

FIG. 1 is a diagram of a multi-layered selector (108) in a crossbar array (102) according to one example of the principles described herein. As described above, a crossbar array (102) may be used in a variety of applications, including random access memory, non-volatile solid state memory, programmable logic, signal processing, control systems, pattern recognition, and other applications. The crossbar array (102) may be used in an electronic device. Examples of electronic devices include servers, desktop computers, laptop computers, personal digital assistants (PDAs), mobile devices, smartphones, gaming systems, and tablets, among other electronic devices.

In some examples, a crossbar array (102) may he coupled to hardware components. Among these hardware components may be a number of processors and a number of data storage devices. A processor may include hardware architecture to retrieve executable code from the data storage device and execute the executable code. The executable code may, when executed by the processor, cause the processor to implement at least the functionality associated with the crossbar array, such as the applications mentioned above. The data storage device may store data such as executable program code that is executed by the processor or other processing device. The data storage device may specifically store computer code representing a number of applications that the processor executes to implement at least the functionality described herein. The data storage device may include a computer readable medium, a computer readable storage medium, or a non-transitory computer readable medium, among others. While FIG. 1 specifically depicts a selector (108) and a memory element (110) such as a memristor in a crossbar array (102), the selector (108) and memory element (110) described herein may be formed in any type of array configuration such as a 1 selector to 1 memristor (1S1M) structure, or a 1 selector ton memristor (1SnM), where n is greater than 1. However, for simplicity a crossbar array (102) is referenced throughout the specification. For simplicity in FIG. 1, one selector (108) and one memory element (110) are indicated with reference numerals.

The crossbar array (102) includes a number of first lines (104-1, 104-2, 104-3) that are indicated in FIG. 1 as rows. The first lines (104) may be approximately parallel to one another. The crossbar array (102) also includes a number of second lines (106-1, 106-2, 106-3, 106-4) that are indicated in FIG. 1 as columns. The second lines (106) may also be approximately parallel to one another. Even though three first lines (104) and four second lines (106) are depicted in FIG. 1, any number of first lines (104) and second lines (106) may be present in the crossbar array (102). As depicted in FIG. 1, the first lines (104) and the second lines (106) may be orthogonal to one another. The two layers of lines (104, 106) form a crossbar, each of the first lines (104) overlaying the second lines (106) and coming into close contact with each second line (106) at intersections that represent the closest contact between each line. While FIG. 1 depicts the lines (104, 106) as having rectangular cross sections, the lines (104, 106) can have other cross sectional geometries including square, circular, elliptical or more complex cross sections.

The lines (104, 106) may function to effectuate voltage drops across the memory elements (110). For example, a target first line (104-1) that corresponds to a target memory element (110) may supply a first portion of an access voltage to the target memory element (110) while a target second line (106-2) applies a second portion of the access voltage to the target memory element (110). The difference between the first portion and second portion generating a voltage drop across the target memory element (110) equal to the access voltage. The access voltage may be either a voltage less than the switching voltage of the target memory element (110), i.e., a read voltage, or may be greater than the switching voltage of the target memory element (110), i.e., a write voltage. In some examples, the voltage supplied by the target first line (104-1) may be the access voltage and the target second line (106-2) may be grounded. The remaining non-target first lines (104-2, 104-3) and non-target second lines (106-1, 106-3, 106-4) may see a non-access voltage drop that is less than a threshold voltage of the selectors (108).

At the intersection of each of the number of first lines (104) and each of the number of second lines (106) is a memory element (110) such as a memristor; a memristor being a non-volatile memory element (110). For simplicity one memory element (110) is indicated with a reference number, this memory element (110) may also indicate a target memory element (110) that is intended to be written to or read from.

A memristor can be used to represent a number of bits of data. For example, a memristor in a low resistance state may represent a logic value of “1.” The same memristor in a high resistance state may represent a logic value of “0.” Each logic value is associated with a resistance state of the memristor such that data can be stored in a memristor by changing the resistance state of the memristor. This may be done by applying an access voltage to a target memory element (110) by passing voltages to target lines that correspond to the target memory element (110).

A memristor is a specific type of memory element (110) that can change resistances by transporting dopants within a switching layer to increase or decrease the resistivity of the memristor. As a sufficient voltage is passed across the memristor, the dopants become active such that they move within a switching layer of the memristor and thereby change the resistance of the memristor.

A memristor is non-volatile because the memristor maintains its resistivity, and indicated logic value, even in the absence of a supplied voltage. In this manner, the memristors are “memory resistors” in that they “remember” the last resistance that they had.

Memristors can be made in a number of geometries and using a variety of materials. One form is a metal-insulator-metal memristor. The term metal is meant to refer broadly to indicate a conductor, for instance doped silicon. A memristor may include a bottom electrode (metal), a switching layer (insulator), and a top electrode (metal). The switching layer may be an insulator between the bottom electrode and the top electrode. For example, in a first state, the switching layer may be insulating such that current does not readily pass between the bottom electrode and the top electrode. Then, during a switching event, the switching layer may switch to a second state, becoming conductive. In a conductive state, the switching layer allows a memristor to store information by changing the memristor state.

In some examples, the top electrode and bottom electrode of the memristor may be formed from a metallic material such as tantalum or a tantalum-aluminum alloy, or other conducting material such as titanium, titanium nitride, copper, aluminum, platinum, and gold among other metallic materials. The switching layer may be made of a metallic oxide. Specific examples of switching layer materials include magnesium oxide, titanium oxide, zirconium oxide, hafnium oxide, vanadium oxide, niobium oxide, tantalum oxide, chromium oxide, molybdenum oxide, tungsten oxide, manganese oxide, iron oxide, cobalt oxide, copper oxide, zinc oxide, aluminum oxide, gallium oxide, silicon oxide, germanium oxide, tin dioxide, bismuth oxide, nickel oxide, yttrium oxide, gadolinium oxide, and magnesium oxide, among other oxides. In addition to the binary oxides presented, the switching layer may be ternary and complex oxides such as silicon oxynitride.

A memristor may be classified as an anion device which includes an oxide insulator as the switching layer. Examples of such oxide insulators include transition metal oxides, complex oxides, and large band gap dielectrics in addition to other non-oxide materials. In this example, a tantalum oxide may be an example of a switching layer in an anion device. In an anionic device, the switching mechanism is the formation of oxygen vacancies in the oxide that are positively charged and therefore lead to the formation of conducting channels in the switching layer. By comparison, in a cation device the conducting channel is formed from an electrochemically active metal such as copper or silver. In some examples, a memristor may be both an anionic device and a cationic device. For example, an aluminum-copper-silicon alloy oxide based memristor could be an anionic device when the copper concentration is low or a cationic device when the copper concentration is high.

As described above, memory elements (110) within a crossbar array (102) may indicate a logic value which may be determined based on a resistance state of the memory element (110). To read the resistance state of a particular memory element (110), an access voltage may be applied to a memory element (110). For example, to read the resistance of a target memory element (110) a first portion of the access voltage, i.e., a positive voltage may be applied to a target first line (104-1). Similarly, a second portion, for example, a negative polarity voltage may be applied to a target second line (106-2). The resulting voltage drop across the memory element (110) creates a current flow that is indicated by the short/long dashed line (112). Sensing circuitry measures the target output current along the target second line (106-2). From the target output current a device determines the resistance, and logic value, indicated by the target memory element (110).

However, as described above, the applied voltages also cause electron flow across other memory elements (110), such as those elements that share the target first line (104-1) and target second line (106-2) with the target memory element (110) and other memory elements. The voltage drop across the partially-selected memory elements (110), and other voltage drops that may be the result of voltages less than the access voltage being passed across non-target lines (104-2, 104-3, 106-1, 106-3, 106-4) generate sneak currents, such as the sneak current indicated by the dashed line (114). Sneak currents can obscure the reading of the target memory element (110) resistance state. The impact of the sneak current increases as the size of the crossbar array (102) increases such that large enough sneak currents may make an accurate reading of a target memory element (220-2) impossible.

Accordingly, the present specification describes devices and methods for reducing the sneak current, and detection of sneak current, in an array such as a crossbar array (102). In this example, a selector (108) may be disposed in series with the memory element (110). For simplicity one selector (108) is indicated with a reference number, however each memory element (110) may have a corresponding selector (108) placed serially in line with the memory element (110). Moreover, while FIG. 1 depicts a selector (108) on top of a memory element (110), any orientation of selector (108) and memory element (110) is possible, such as a memory element (110) on top of a selector (108).

The selector (108) is an element that allows electrons to flow through a memory element (110) or that prevents electrons from flowing through the memory element (110). For example, the selector (108) may have a threshold voltage. When a supplied voltage is less than the threshold voltage of the selector (118), no voltage is seen by the memory element (110). As such, no current flows through the memory element (110). Similarly, in this example, when the supplied voltage is greater than the threshold voltage of the selector (108), the supplied voltage is seen by the memory element (110) and a current is passed through the memory element (110) and an output current received by the sensing circuitry along the second lines (106).

In some examples, the selector (108) may be a multi-layered selector (108). As used in the present specification and in the appended claims the term multi-layered selector (108) may refer to a selector (108) that has been formed by alternating deposition of at least a dielectric layer and a first diffusion layer. In some examples, the multi-layered selector (108) may include multiple instances of a dielectric layer, a first diffusion layer, and a second diffusion layer. The first and second diffusion layers may have different compositions. For example, each of the first and second diffusion layers may he composed of at least one of silver, copper, nickel, silver oxide, copper oxide, and nickel oxide. In this example, each of the first and second diffusion layers may include different combinations of the above described elements and at different quantities.

As the multi-layered selector (108) is post-treated, the diffusion layers may no longer be distinguishable from one another such that the select (108) appears as a matrix material with the ions that made up the diffusion layers diffused throughout the matrix material. However, forming a multi-layered selector (108) by alternately depositing layers of at least the first diffusion layer and dielectric layer may yield a selector (108) with high nonlinearity and a high current density so as to effectively isolate unselected and partially-selected memory elements (110) from a target memory element (110). For example, the nonlinearity of a multi-layered selector (108) may be greater than 1000. In other words, a difference in two output currents may be at least 1,000 times greater than a difference in voltages used to generate the currents. In a specific numerical example, a current generated by a voltage value “V,” may be 2,000 times greater than a current generated by a voltage value “V12.”

As will be described below, the diffusion layers may be made up of silver, copper, nickel, silver oxide, copper oxide, or nickel oxide. In some examples the different diffusion layers may have combination of the above elements to generate layers with different diffusion rates, a diffusion rate referring to the rate at which ions that make up the layer diffuse through a matrix. For example, the first diffusion layer may include silver oxide which may diffuse faster than copper oxide which forms the second diffusion layer.

Using different diffusion layers each layer having different combinations of ions to generate layers with different diffusion rates may allow for a simplified manufacturing process to generate a highly nonlinear and high current density selector to more efficiently reduce, or detach the effects of, sneak current in a crossbar array (102). Moreover the use of silver, copper, nickel, silver oxide, copper oxide, and nickel oxide in various thicknesses allows for great flexibility in forming a selector (108) with particular characteristics. Moreover the use of fast diffusive metals such as silver, copper, nickel, silver oxide, copper oxide, and nickel oxide may result in localized conducting channels of fast diffusive metals that are formed by the rearrangement of the metal elements during the post-fabrication treatments or electrical operations.

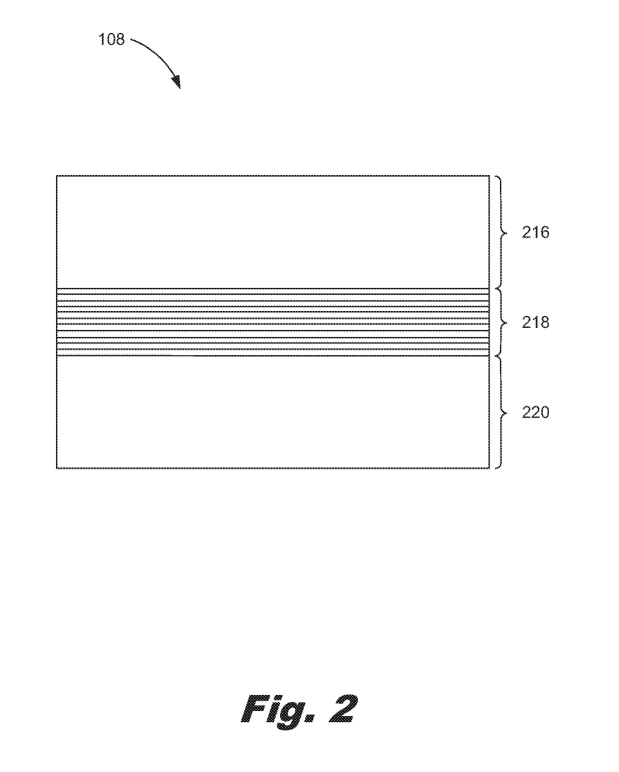

FIG. 2 is a cross-sectional diagram of a multi-layered selector (108) according to one example of the principles described herein. The multi-layered selector (108) may include a first electrode (216). In some examples, the first electrode (216) may be positioned on top of a diffusion region (218) of the multi-layered selector (108). The first electrode (216) may form an electric coupling between the selector (108) and an external energy supply. For example, the first electrode (216) as disposed on a top of the memory element (FIG. 1, 110) may receive a programming energy such as a voltage pulse from a first line (FIG. 1, 104). The multi-layered selector (108) may also include a second electrode (220). In some examples, the second electrode (220) may be positioned below a diffusion region (218) of the multi-layered selector (108). The second electrode (220) may form an electric coupling between the selector (108) and a memory element (FIG. 1, 110). For example, the second electrode (220) of the selector (108) may be in electrical communication with a top electrode of a memristor memory element (FIG. 1, 110).

In some examples, the first electrode (216) and second electrode (220) of the selector (108) may be formed from a metallic material such as tantalum or a tantalum-aluminum alloy, or other conducting material such as titanium, titanium nitride, copper, aluminum, platinum, and gold among other metallic materials.

Disposed between the top electrode (216) and the bottom electrode (220) is a diffusion region (218) that is formed by alternately depositing instances of at least a dielectric layer and a first diffusion layer. After formation, and during operation, the material in the dielectric layer may operate as a matrix and the ions that make up the first diffusion layer may distribute throughout the matrix.

The first diffusion layer may be made up of a number of ions to form a layer with a first diffusion rate. In some examples, the diffusion region (218) may include a second diffusion layer. The second diffusion layer may be made up of a number of ions that form a layer having a second diffusion rate, the second diffusion rate being different then the first diffusion rate. Both the ions in the second diffusion layer and the first diffusion layer may be fast diffusive ions. In other words, the diffusive ions in the first and second diffusion layers may diffuse faster in an oxide as compared to normal oxygen vacancies or oxygen anions disposed in the same oxide at the same temperature. Ions in the first diffusion layer may diffuse faster than ions in the second diffusion layer. The different diffusion layers may be made up of silver, copper, nickel, silver oxide, copper oxide, and nickel oxide to achieve an intended threshold voltage of the completed selector (108).

For example, a selector (108) may have a threshold voltage that when exceeded allows the programming energy, i.e., the access voltage, to pass through to the memory element (FIG. 1, 110) such that a resistance level of the memory element (FIG. 1, 110) may be changed or read in a write or read operation. A voltage passed through an electrode (216, 220) that is less than the threshold voltage of the selector (108) is not passed to the corresponding memory element (FIG. 1, 110) while a voltage passed through an electrode (216, 220) that is larger than the threshold voltage of the selector (108) is passed through to the memory element (FIG. 1, 110) such that a voltage drop across the memory element (FIG. 1, 110) is seen and detected. A threshold voltage for the selector (108) may be selected by varying the material used for the first and second diffusion layers as well as the thickness of the layers.

The selector (108) along with the memory element (FIG. 1, 110) make up a memory cell, for example that is disposed at an intersection between a first line (FIG. 1, 104) and a second line (FIG. 1, 106) of a crossbar array (FIG. 1, 102). In some examples, the selector (108) may have distinct electrodes (216, 220) from the electrodes of the memory element (FIG. 1, 110) and may be oriented in various fashions relative to the memory element (FIG. 1, 110). For example, a memory cell stack may be, from bottom to top, selector second electrode (220), selector diffusion region (218), selector first electrode (216), memristor bottom electrode, memristor switching layer, and memristor top electrode. In another example, a memory cell stack may be, from bottom to top, memristor bottom electrode, memristor switching layer, memristor top electrode, selector second electrode (220), selector diffusion region (218), and selector first electrode (216).

In other examples, the memory element (FIG. 1, 110) and selector may share an electrode. For example, a memory cell stack may be, from bottom to top, selector second electrode (220), selector diffusion region (218), a layer that makes up the selector first electrode (216) and memristor bottom electrode, memristor switching layer, and memristor top electrode. In another example of shared layers, a memory cell stack may be, from bottom to top, memristor bottom electrode, memristor switching layer, a layer that makes up the memristor top electrode and the selector second electrode (220), selector diffusion region (218), and selector first electrode (216).

In yet another example, one of the electrodes may be absent from at least one of the memory element (FIG. 1, 110) and selector (108). For example, a memory cell stack may be from bottom to top, selector second electrode (220), selector diffusion region (218), memristor switching layer, and memristor top electrode. In another example, a memory cell stack may be from bottom to top, memristor bottom electrode, memristor switching layer, selector diffusion region (218), and selector first electrode (216).

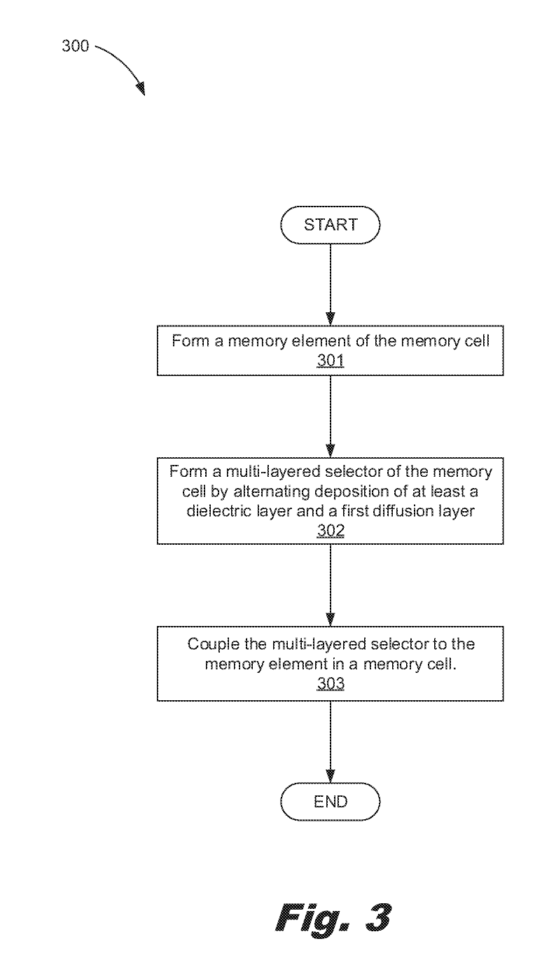

FIG. 3 is a flow diagram of a method (300) for forming a multi-layered selector (FIG. 1, 108) of a memory cell, according to one example of the principles described herein. As described above, a first line (FIG. 1, 104) of a memory array such as a crossbar array (FIG. 1, 102) may intersect with a second line (FIG. 1, 106) of the crossbar array (FIG. 1, 102) and at such intersection, a memory cell may be disposed, the memory cell including a memory element (FIG. 1, 110) and a selector (FIG. 1, 108) in electrical communication with the memory element (FIG. 1, 110). Accordingly, the method (300) may include forming (block 301) a memory element (FIG. 1, 110) of the memory cell. In some examples, the memory element (FIG. 1, 110) may be a resistive memory element (FIG. 1, 110) such as a memristor. As memristors may have a metal-insulator-metal structure, forming (block 301) a memory element (FIG. 1, 110) of the memory cell may include forming the layers, i.e., bottom electrode, switching layer, and top electrode, which make up the memristor. The memory element (FIG. 1, 110) may store bits of information in binary form, which bits may be indicated by a resistance level of the memory element (FIG. 1, 110). A number of memory elements (FIG. 1, 110) such as memristors in different high and low resistance states may generate strings of logical values such as 1 and 0 that may indicate information stored in the memory array.

The method (300) also includes forming (block 302) a multi-layered selector (FIG. 1, 108) of the memory cell by alternating deposition of at least a dielectric layer and a first diffusion layer, which first diffusion layer includes fast diffusive ions. More specifically, a diffusion region (FIG. 2, 218) of the selector (FIG. 1, 108) may be formed by alternately depositing the dielectric layer and a number of diffusion layers. In one example, the dielectric layer may be formed from at least one of silicon oxide, hafnium oxide, tantalum oxide, zirconium oxide, aluminum oxide, silicon nitride, aluminum nitride, and titanium oxide. The dielectric layer may have a resistivity of at least 1000 ohm-centimeters (Ω·cm). The dielectric layer may not have ions that diffuse quickly. By comparison, the diffusion layers such as the first diffusion layer and second diffusion layer may have ions that diffuse quicker than the ions in the dielectric layer. The first diffusion layer may have lower resistivity than the dielectric layer. The first diffusion layer may include ions that diffuse quickly through a matrix material. Examples of the first diffusion layer material include silver, copper, nickel, silver oxide, copper oxide, and nickel oxide. In a post-formation treatment, the ions may diffuse through the dielectric layer to form a matrix of dielectric material with ions of material from the first diffusion layer disperse throughout.

In some examples, forming (block 302) a multi-layered selector (FIG. 1, 108) may include alternately depositing the dielectric layer, a first diffusion layer, and other diffusion layers such as a second diffusion layer. The second diffusion layer may also include ions that diffuse quickly through a matrix material. Similar to the first diffusion layer, the second diffusion layer may include ions of silver, copper, nickel, silver oxide, copper oxide, or nickel oxide, but that is different from the ions that are included in the first diffusion layer. In some examples the second diffusion layer may be a different thickness than the first diffusion layer. In this example, the properties (i.e., compounds used and layer thicknesses) may be manipulated to generate a diffusion region (218) with desired characteristics. Forming (block 302) a multi-layered selector (FIG. 1, 108) may include depositing multiple instances of each of the dielectric layer, the first diffusion layer, and any other diffusion layer formed as part of the multi-layered selector (FIG. 1 108).

The method (300) includes coupling (block 303) the multi-layered selector (FIG. 1, 108) to the memory element (FIG. 1, 110) in a memory cell. As described above, a selector (FIG. 1, 108) may be used to allow or prevent current from passing through a corresponding memory element (FIG. 1, 110). Accordingly, the multi-layered selector (FIG. 1, 108) may be coupled serially to the memory element (FIG. 1, 110) within a memory cell. Coupling (block 303) the multi-layered selector (FIG. 1, 108) to the memory element (FIG. 1, 110) may include depositing the selector (FIG. 1, 108) on a surface of the memory element (FIG. 1, 110). For example, the selector (FIG. 1, 108) may be disposed such that a first electrode (FIG. 2, 216) of the selector (FIG. 1, 108) is adjacent to a bottom electrode of the memory element (FIG. 1, 110). In another example, the selector (FIG. 1, 108) may be disposed such that the second electrode (FIG. 2, 220) of the selector (FIG. 1, 108) is disposed adjacent to a top electrode of the memory element (FIG. 1, 110). In other examples, the memory element (FIG. 1, 110) and selector (FIG. 1, 108) may be disposed such that they share an electrode as described above or may be disposed such that at least one of either component (the memory element (FIG. 1, 110) and the selector (FIG. 1, 108)) is missing an electrode.

As described above a multi-layered selector (FIG. 1, 108) formed from deposition of layers of diffusion material may allow for easy deposition of various types of ions with different diffusion rates in a diffusion region (FIG. 2, 228) of a selector to generate a highly nonlinear selector that is easy and cost-effective to fabricate. Such layered deposition also allows for great flexibility and control in the selector (FIG. 1, 108) fabrication operation.

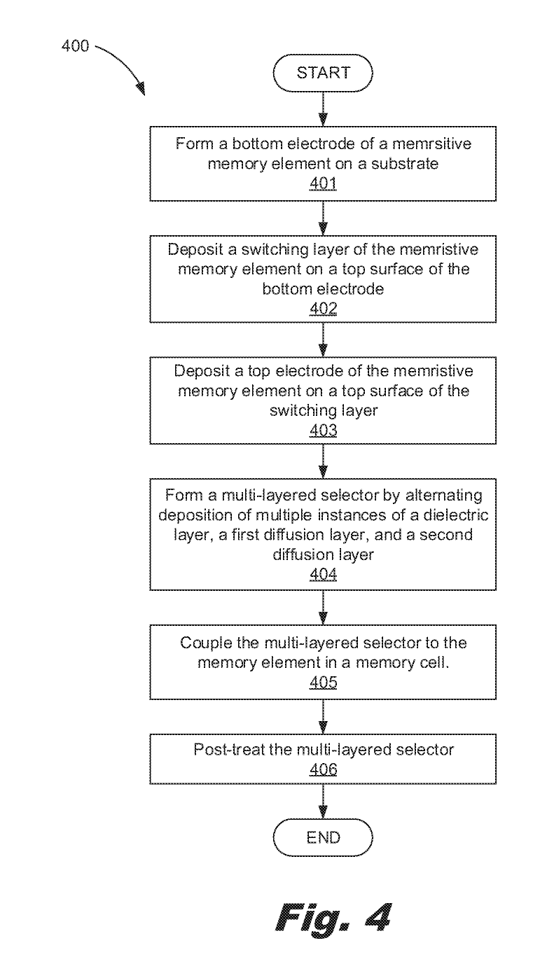

FIG. 4 is a flow diagram of a method (400) for forming a multi-layered selector (FIG. 1, 108) of a memory cell, according to another example of the principles described herein. In some examples, the memory cell may be a memristive memory cell that includes a resistive memory element (FIG. 1, 110) such as a memristor. Accordingly, the method (400) may include forming (block 401) a bottom electrode of a memristive, memory element (FIG. 1, 110) on a substrate. The bottom electrode may be formed by a number of processes include chemical vapor deposition, etching, lithography or any number of processes.

The method (400) also includes depositing (block 402) a switching layer of the memristive memory element (FIG. 1, 110) on a top surface of the bottom electrode of the memristive memory element (FIG. 1, 110). The switching layer may be formed by any number of processes including chemical vapor deposition, plasma deposition, etching, and lithography among other fabrication methods.

The method (400) also includes depositing (block 403) a top electrode of the memristive memory element (FIG. 1, 110) on a top surface of the switching layer. In other words, the bottom electrode of the memristor may be disposed on one surface of the switching layer and the top electrode of the memristor may be disposed on an opposite surface of the switching layer to form a metal-insulator-metal memristor structure.

The method (400) also includes forming (block 404) a multi-layered selector (FIG. 1, 108). More specifically, alternating layers of a dielectric material, and at least a first diffusion layer and a second diffusion layer may be deposited in layers to form a multi-layered selector (FIG. 1, 108). In some examples, the different layers may have different thicknesses. For example, the dielectric layer may have a first thickness and the first diffusion layer and second diffusion layer may have a second thickness that is thinner than the first thickness. The different thicknesses may afford another degree of flexibility in selecting a threshold voltage for a selector (FIG. 1, 108).

The method (400) also includes coupling (block 405) the multi-layered selector (FIG. 1, 108) to the memory element (FIG. 1, 110) in a memory cell. This may be performed as described in connection with FIG. 3.

The method (400) includes post-treating (block 406) the multi-layered selector (FIG. 1, 108). Such post-treatment processes may include, annealing, thermal annealing, and exposing the selector (FIG. 1, 108) to ultraviolet light, and electrically-stressing the selector (FIG. 1, 108) with a voltage, among other post-treatment processes. Such post treatments may break down the identifiable layers of the selector (FIG. 1, 108) such that a cross-section of the selector (FIG. 1, 108) after post treatment may indicate a matrix of material, such as the material in the dielectric layer, with ions from the different diffusion layers distributed throughout. The method (400) may allow for a ion-diffused matrix structure in the selector (FIG. 1, 108) while providing a simple manufacturing technique that includes depositing layers of material that have ions with different ion diffusion rates. Such a layered-deposition process may simplify manufacturing and allow for customization of selector (FIG. 1, 108) characteristics.

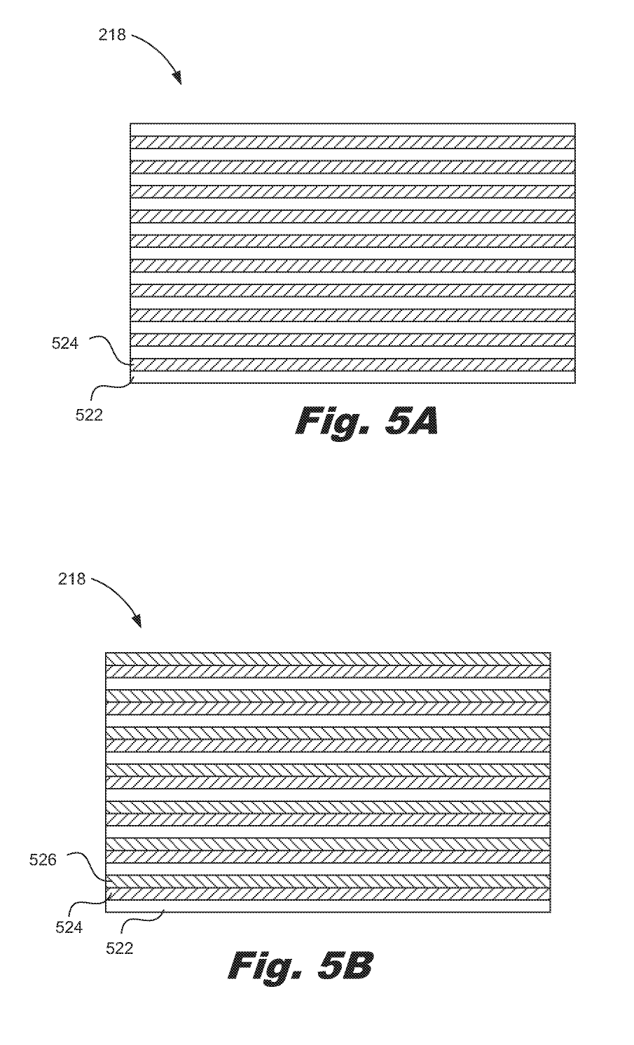

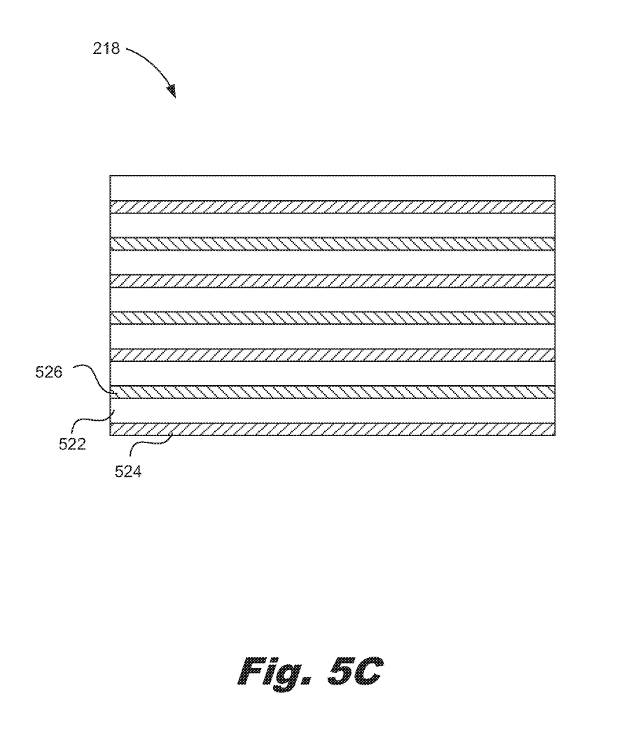

FIGS. 5A-5C are cross-sectional diagrams of a multi-layered selector (FIG. 1, 108), according to examples of the principles described herein. More specifically, FIGS. 5A-5C depict cross-sectional diagrams of a diffusion region (218) of the multi-layered selector (FIG. 1, 108). While FIGS. 5A-5C depict particular cross-hatchings, such cross-hatchings are not meant to indicate a particular material, but rather to distinguish between the different layers. Layers having a similar pattern, i.e., no fill, cross-hatchings having the same angle, i.e., sloping +45° and sloping −45°, are meant to indicate layers of material having the same characteristics. While FIGS. 5A-5C depict different layering configurations, any layering configuration may be used. Moreover, the layering depicted in FIGS. 5A-5C is indicative of a layering that occurs during fabrication. During a post-treatment process and during operation, the diffusion region (218) may appear as a matrix of a dielectric material with ions from the diffusion layers distributed throughout.

FIG. 5A is a cross-sectional diagram of a diffusion region (218) having layers of a dielectric material (522) and a first diffusion layer (524). For simplicity a single instance of each is indicated by a reference number, however each layer having similar patterning is intended to indicate layers having similar characteristics. As described above, multiple instances of each layer may make up the diffusion region (218) of the multi-layered selector (FIG. 1, 108). The first diffusion layer (524) may have a lower resistivity than the dielectric layer (522). As described above, the first diffusion layer (524) may include silver, copper, nickel, silver oxide, copper oxide, or nickel oxide.

FIG. 5B is a cross-sectional diagram of a diffusion region (218) having multiple instances of a dielectric material (522), a first diffusion layer (524), and a second diffusion layer (526). For simplicity a single instance of each is indicated by a reference number however each layer having similar patterning is intended to indicate layers having similar characteristics. As described above, multiple instances of each layer may make up the diffusion region (218) of the multi-layered selector (FIG. 1, 108). The first diffusion layer (524) and second diffusion layer (526) may have a lower resistivity than the dielectric layer (522). The first diffusion layer (524) and the second diffusion layer (526) may have ions with different diffusion rates. For example, the first diffusion layer (524) may have ions with a first diffusion rate and the second diffusion layer (526) may have ions with a second diffusion rate. The first diffusion layer (524) and second diffusion layer (526) may include ions selected from silver, copper, nickel, silver oxide, copper oxide, and nickel oxide so as to provide layers having ions with different diffusion rates.

FIG. 5C is a cross-sectional diagram of a diffusion region (218) having multiple instances of a dielectric material (522), a first diffusion layer (524), and a second diffusion layer (526). For simplicity, a single instance of each is indicated by a reference number however each layer having similar patterning is intended to indicate layers having similar characteristics. As described above, multiple instances of each layer may make up the diffusion region (218) of the multi-layered selector (FIG. 1, 108). The first diffusion layer (524) and second diffusion layer (526) may have a lower resistivity than the dielectric layer (522). The first diffusion layer (524) and the second diffusion layer (526) may have ions with different diffusion rates. For example, the first diffusion layer (524) may have ions with a first diffusion rate and the second diffusion layer (526) may have ions with a second diffusion rate. The first diffusion layer (524) and second diffusion layer (526) may include different ions selected from silver, copper, nickel, silver oxide, copper oxide, and nickel oxide so as to provide layers having ions with different diffusion rates.

As depicted in FIG. 5C, the different layers may have different thicknesses. For example, the dielectric layer (522) may have a first thickness and the first diffusion layer (524) and the second diffusion layer (526) may have a second, and thinner, thickness.

The preceding description has been presented to illustrate and describe examples of the principles described. This description is not intended to be exhaustive or to limit these principles to any precise form disclosed. Many modifications and variations are possible in light of the above teaching.

What is claimed is:

1. A method for forming a multi-layered selector of a memory cell, the method comprising:
forming a memory element of the memory cell, the memory element to store information;
forming a multi-layered selector of the memory cell by alternating deposition of at least a dielectric layer and a first diffusion layer, in which the first diffusion layer comprises fast diffusive ions; and
coupling the multi-layered selector to the memory element in a memory cell.

2. The method of claim 1, in which forming a memory element comprises forming a memristive memory element by:
forming a first electrode of the memristive memory element;
forming a switching layer of the memristive memory element, in which the first electrode is in contact with a first surface of the switching layer; and
forming a second electrode of the memristive memory element, in which:
the second electrode is in contact with a second surface of the switching layer; and
the second surface is opposite the first surface.

3. The method of claim 1, in which forming a multi-layered selector comprises alternating deposition of at least a dielectric layer, a first diffusion layer, and a second diffusion layer, in which the second diffusion layer comprises fast diffusive ions.

4. The method of claim 3, in which ions in the first diffusion layer have a higher diffusion rate than ions in the second diffusion layer.

5. The method of claim 1, in which the dielectric layer is selected from silicon oxide, hafnium oxide, tantalum oxide, zirconium oxide, aluminum oxide, silicon nitride, aluminum nitride, and titanium oxide.

6. The method of claim 1, in which the first diffusion layer is selected from silver oxide, copper oxide, nickel oxide, silver, copper, and nickel.

7. The method of claim 3, in which the second diffusion layer is selected from silver oxide, copper oxide, nickel oxide, silver, copper, and nickel.

8. The method of claim 1, further comprising post-treating the multi-layered selector.

9. A memory cell with a multi-layered selector, comprising:
a memory element comprising:
a bottom electrode disposed on a substrate;
a top electrode disposed above the bottom electrode;
a switching layer disposed between the top electrode and the bottom electrode; and
a multi-layered selector communicatively coupled to the memory element, in which the multi-layered selector comprises alternating layers of at east a dielectric material and a first diffusion layer, in which the first diffusion layer comprises at least one of silver oxide, copper oxide, nickel oxide, silver, copper, and nickel.

10. The cell of claim 9, in which the multi-layered selector comprises at least a second diffusion layer, in which the second diffusion layer comprises at least one of silver oxide, copper oxide, nickel oxide, silver, copper, and nickel.

11. The cell of claim 10, in which the multi-layered selector comprises multiple layers of at least one of the dielectric material, the first diffusion layer, and the second diffusion layer.

12. The cell of claim 9, in which the resistivity of the dielectric layer is at least 1000 ohm-centimeters (Ω·cm).

13. A method for forming a memory cell with a multi-layered selector, the method comprising:
forming a bottom electrode of a memristive memory element on a substrate;
depositing a switching layer of the memristive memory element on a top surface of the bottom electrode;
depositing a top electrode of the memristive memory element on a top surface of the switching layer
forming a nonlinear multi-layered selector with fast diffusive conduction channels by alternately depositing layers of each of:
a dielectric material including at least one of silicon oxide, hafnium oxide, tantalum oxide, zirconium oxide, aluminum oxide, titanium oxide, silicon nitride, and aluminum nitride;
a first diffusion layer having ions with a first diffusion rate, the first diffusion layer comprising at least one of silver oxide, copper oxide, nickel oxide, silver, copper, and nickel; and
a second diffusion layer having ions with a second diffusion rate, in which:
the second diffusion rate is less than the first diffusion rate; and
the second diffusion layer comprises at least one of silver oxide, copper oxide, nickel oxide, silver, copper, and nickel; and
communicatively coupling the nonlinear multi-layered selector to at least one of the top electrode of the memristive memory element and the bottom electrode of the memristive memory element.

14. The method of claim 13, in which forming a nonlinear multi-layered selector by alternately depositing layers a dielectric material, a first diffusion layer, and a second diffusion layer comprises depositing multiple layers of each of the dielectric material, the first diffusion layer, and the second diffusion layer.

15. The method of claim 13, in which the alternating layers have different thicknesses.
